(19) United States
(12) Patent Application Publication
(10) Pub. No.: US 2014/0225135 A1
(43) Pub. Date: Aug. 14, 2014

(54) Optical Device Array Substrate Having a Heat Dissipating Structure Integrated with a Substrate, and Method for Manufacturing Same

(71) Applicant: Point Engineering Co., LTD, Asan-si, Chungcheongnam-do (KR)

(72) Inventors: Bum Mo Ahn, Yongin-si (KR); Ki Myung Nam, Cheonan-si (KR); Young Chul Jun, Ansan-si (KR)

(21) Appl. No.: 14/343,674

(22) PCT Filed: Jul. 26, 2012
(86) PCT No.: PCT/KR2012/005958

§ 371 Date: Mar. 7, 2014

(30) Foreign Application Priority Data
Sep. 9, 2011 (KR) 10-2011-0091972

(51) Int. Cl. H01L 33/64

(52) U.S. Cl. CPC H01L 33/648
USPC 257/88; 438/34

(57) ABSTRACT

The present invention relates to an optical device array substrate having a built-in heat dissipating structure, and to a method for manufacturing same, wherein the optical device array substrate itself is used as a heat sink and a coupling hole is formed at the bottom of the substrate to have a heat dissipating rod coupled thereto. The optical device array substrate having a built-in heat dissipating structure of the present invention consists essentially of: an optical device array substrate having a plurality of optical devices arranged on the top surface thereof and a plurality of coupling holes formed in the bottom surface thereof; and rod-shaped heat dissipating rods that have coupling projections formed on upper ends thereof, and are coupled to each of the coupling holes. In the above-described structure, the coupling holes are threaded, and the coupling projections are also threaded so as to be screw-coupled to the coupling holes. The coupling holes are formed having a downwardly narrowing taper, and the coupling projections are formed having a downwardly narrowing taper so as to be precisely coupled with the coupling holes even when in a contracted state under sub-freezing temperatures. The surfaces of the heat dissipating rods are characterized in that insulation coating layers are formed thereon and not on the coupling projections. A portion of the insulation coating layers on some of the heat dissipating rods may be removed to function as electrodes.

### TECHNICAL FIELD

This invention relates to an optical device array substrate having a built-in heat dissipating structure, and method for manufacturing same, more particularly, to an optical device array substrate having a built-in heat dissipating structure, wherein the optical device array substrate itself is used as a heat sink and coupling holes are formed at the bottom of the substrate to have the heat dissipating rods coupled thereto

### BACKGROUND ART

Generally, semiconductor light emitting diode (LED) receives attention from various fields as an environment friendly light source. Recently, as applications of LEDs are expanding to various fields such as interior and exterior illuminations, automobile headlights, and back-light units (BLU) of display devices, there are needs for high optical efficiency and excellent heat radiation characteristics. For high efficiency LEDs, materials or structures of the LEDs should be improved primarily, however there is a need for improvement in the structures of the LED packages and the materials used therein.

In such high efficiency LEDs, high temperature heat is produced, therefore this heat must be radiated effectively otherwise temperature rising on the LEDs causes ageing of the characteristics thereby shortening the lifetime. In high efficiency LED packages, efforts on effective radiation of the heat produced by the LEDs are making progress.

Hereinafter, any kind of device that emits light including LED will be referred to as ‘optical device,’ and any product where more than two optical devices are arranged in a matrix form will be referred to as ‘optical device array.’ A horizontal arrangement of optical devices (or substrates) is called ‘row,’ and a vertical arrangement is called ‘column,’ thus, while vertically arranged optical devices in each column are connected each other in parallel, horizontally arranged optical devices in each row are connected in serial.

FIG. 1 is a perspective view of an example of an optical device array using vertical insulation layers of the prior art. As shown in FIG. 1, in an optical device array using vertical insulation layers of the prior art, more than two insulation layers 32 (referred to as ‘vertical insulation layer’) which penetrates the substrate 30 (for example, an aluminum or a copper substrate) from top to bottom are formed therein, therefore two neighboring segments of the substrate are insulated by the corresponding vertical insulation layer 32 located between said neighboring segments.

In such configuration, while a terminal, for example, an anode terminal at the one end of an optical device 40 disposed in any one column (referenced to a vertical insulation layer 32) is electrically connected to the substrate of the corresponding column via wire 42 and the like; a terminal, for example, a cathode terminal at the other end of said optical device is also electrically connected to another substrate of an adjacent column located at the other side of said vertical insulation layer 32 via wire 42 and the like. Therefore a segment of the substrate which is arranged at the end of the left side or at the end of the right side of the substrate could function as an anode and a cathode respectively. Reference number 34 in FIG. 1 represents a cavity comprising a concave pit hole having a downwardly narrowing taper formed across the two columns adjacent to the vertical insulation layer 32 for enhancing the efficiency of the reflected light from the optical device 40, and the optical device 40 and a wire 42 connected thereto are all accommodated inside of the cavity 34.

FIG. 2 is a cross-sectional view showing an example of an optical device array using horizontal insulation layer of the prior art, and only the optical devices of one column are illustrated for convenience. As illustrated in FIG. 2, in an optical device array using a horizontal insulation layer, the optical devices 66 are mounted on top of the substrate 50 (for example, an aluminum or a copper substrate) using adhesive 60 and the like; in the left and the right areas adjacent to the optical device 66 of the substrate 50, an insulation layer 62 is formed keeping a distance from the optical device 66. A conduction layer 64 is formed on each insulation layer 62 such that the anode terminal and the cathode terminal of the optical device 66 are electrically connected to the conduction layer 64 via wire 68. Reference number 70 in FIG. 2 represents a dam to store protective encapsulant 80 containing, for example, fluorescent materials and the like.

FIG. 3 is a schematic cross-sectional view to describe a heat dissipating structure of a general optical device array of the prior art. As shown in FIG. 3, the heat dissipating structure of an optical device array of the prior art is realized by attaching a heat sink 20 to the bottom of the optical device array shown in FIG. 1 or FIG. 2, and said heat sink 20 is comprised of: a heat dissipating plate 22 that is a separate body from the optical device array substrate 10; and many heat dissipating fins 24 that are downwardly expanding in parallel from said heat dissipating plate 22. Such heat sink 20 may be formed as a single structure by extruding aluminum or copper and the like. Meanwhile, in order to prevent degradation of heat dissipating characteristics due to the air gap produced when the optical device substrate 10 and the heat sink 20 are mechanically jointed together, thermal pad or grease are interposed between the optical device substrate 10 and the heat sink 20 for improvement in adhesiveness or insulation property.

However, according to a heat dissipating structure of an optical device array of the prior art as described above, since a heat sink, a physically separate body with respect to the optical device array substrate, being mechanically jointed thereto is used; somehow it causes degradation problem in heat dissipating characteristics due to decreased adhesiveness; considering this problem, thermal pad or grease may be interposed, however, it will result in a complicated process.

Furthermore, since the heat dissipating fins are arranged only in one direction and in parallel, the ventilation air path is formed only in one direction, thereby making heat dissipation difficult.

Meanwhile, a cooler assembly that cools microprocessor, i.e. CPU, using a Peltier device is provided in Korea Patent publication No. 69806 published Sep. 5, 2002; according to this publication, a heat sink which radiates heat occurred at the Peltier device is disclosed, wherein many concave pit holes are arranged in matrix form on one side of a heat radiating plate, and many heat radiating rods made of material that is either identical to or different from the heat radiating plate are assembled into the concave pit holes by applying pressure (insertion by force).

However, since such a heat sink adopts a structure where heat radiating rods of different bodies are connected to the heat radiating plate which is a separate body not the electrically conducting substrate itself, in adopting this structure as it is for a heat radiating structure for optical device array, adhesiveness between the substrate and the heat radiating plate would still be a remaining problem. Besides, since no measures are prepared for electrical insulation, there is a possibility of short circuit when foreign substances are interposed between the heat radiating rods, furthermore, electric shock could happen when handling the device by holding the radiating rods.

### SUMMARY OF INVENTION

### Technical Problem

An objective of the present invention, devised to solve above described problems, is to provide an optical device array substrate having a built-in heat dissipating structure and method for manufacturing same, wherein the optical device array substrate itself is used as a heat sink and coupling holes are formed at the bottom of the substrate to have the heat dissipating rods coupled thereto

### Solution to Problem

To achieve above described objective, an optical device array substrate having a built-in heat dissipating structure of the present invention comprises: an optical device array substrate having multiple optical devices disposed on its upper surface and multiple coupling holes formed on its bottom surface; and at least one coupling rod having a coupling projection formed on top thereof and being coupled into each of respective said coupling holes.

In the above described configuration, said coupling holes are characterized in that said coupling holes are threaded, and said coupling projections are also threaded so as to be screw-coupled to said coupling holes.

On the one hand, each of said coupling holes has a downwardly narrowing taper, and each of said coupling projections also has a downwardly narrowing taper so as to be perfectly coupled into one of said coupling holes even when shrunk under sub-freezing temperatures.

On the other hand, said coupling projections may be formed like a hollow cylinder shape having more than one lengthwise slot, and at the end part of said coupling projection a latch structure having a downwardly widening taper whose top end has a diameter equal or less than that of the body of the coupling projection while bottom end has a diameter greater than that of the body of the coupling projection may be formed, and on top of each of said coupling holes a latching groove may be formed therein for matching with the said latch structure.

A portion of the insulation coating layer of some of said coupling rods may be removed so as to be functioned as an electrode.

According to other feature of the present invention, a manufacturing method an optical device array substrate having a built-in heat dissipating structure includes the steps of: (a) preparing a metal substrate formed with multiple coupling holes on the bottom surface thereof; (b) forming multiple optical devices on the top surface of said metal substrate; (c) preparing a heat dissipating rod formed with a coupling projection at the end part thereof for coupling with said coupling hole; and (d) coupling said coupling projection to said coupling hole after shrinking said heat dissipating rod under sub-freezing temperatures, followed by rising temperature to room temperature.

### Advantageous Effects of Invention

According to an optical device array substrate having a built-in heat dissipating structure and method for manufacturing same of the present invention, since the optical device array substrate itself functions as a heat dissipating plate of the heat sink, heat transfer could occur more easily and quickly, and besides, it does not require deposition process for thermal pads or grease etc., thereby simplifying the process.

Furthermore, since the heat dissipating fin is a rod shaped structure, the heat dissipating surface is increased therefore heat dissipating efficiency can be enhanced and, moreover, ventilation can be accomplished more smoothly. In addition, short circuits occurring due to foreign substances can be prevented by insulation coating and, moreover, the risk of electric shock can be reduced.

### BRIEF DESCRIPTION OF DRAWINGS

FIG. 1 is a perspective view showing an example of an optical device array using vertical insulation coating layer of the prior art.

FIG. 2 is a cross-sectional view showing an example of an optical device array using horizontal insulation coating layer of the prior art.

FIG. 3 is a schematic cross-sectional view to describe a heat dissipating structure of a typical optical device array of the prior art.

FIG. 4 is a cross-sectional view of an optical device array substrate having a vertical insulation coating layer among the optical device array substrate having a built-in heat dissipating structure according to an exemplary embodiment of the present invention.

FIG. 5 is a partial exploded perspective view of the optical device array substrate in FIG. 4 showing the outline of the bottom side thereof.

FIG. 6 is a cross-sectional view of an optical device array substrate having a vertical insulation coating layer among the optical device array substrate having a built-in heat dissipating structure according to another exemplary embodiment of the present invention.

FIG. 7 is a cross-sectional view of an optical device array substrate having a horizontal insulation coating layer among the optical device array substrate having a built-in heat dissipating structure according to an exemplary embodiment of the present invention.

FIG. 7 is a cross-sectional view of an optical device array substrate having a horizontal insulation coating layer among the optical device array substrate having a built-in heat dissipating structure according to another exemplary embodiment of the present invention.

FIG. 9 is a flow diagram to describe manufacturing method of an optical device array substrate having a built-in heat dissipating structure according to an exemplary embodiment of the present invention.

### DESCRIPTION OF EMBODIMENTS

Hereinafter, a preferred exemplary embodiment of the present invention, an optical device array substrate having a built-in heat dissipating structure, and method for manufacturing same, will be described in detail with reference to the accompanying drawings

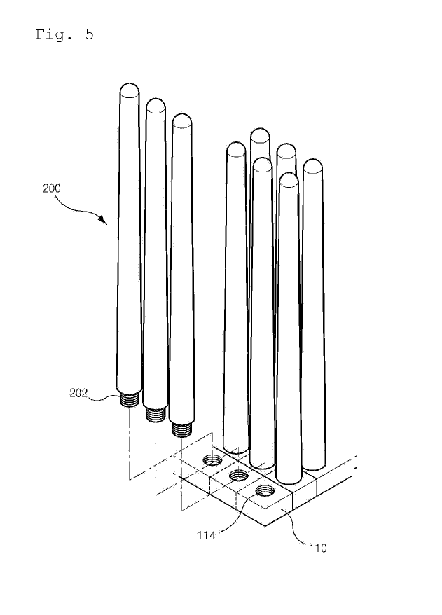

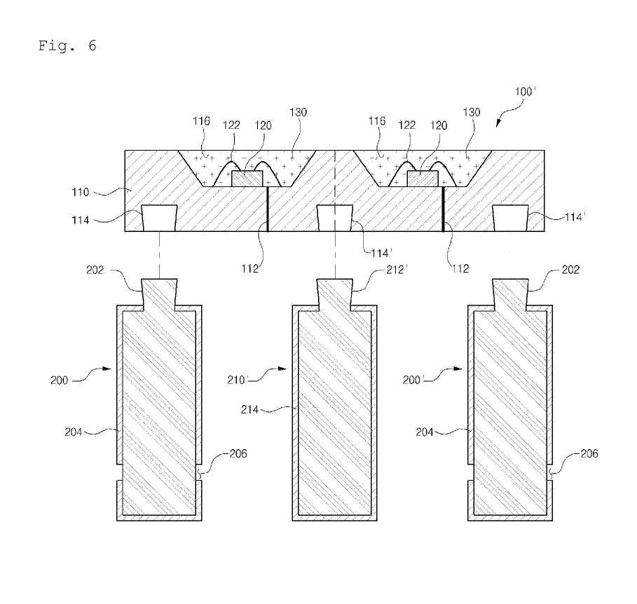

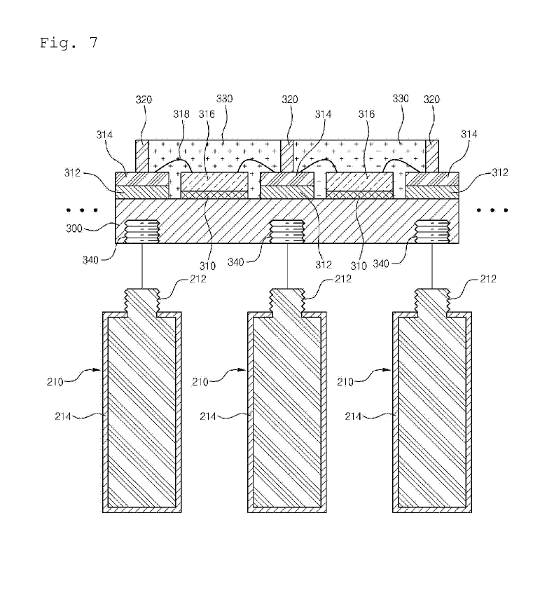

FIG. 4 is a cross-sectional view of an optical device array substrate having a vertical insulation coating layer among the optical device array substrate having a built-in heat dissipating structure according to an exemplary embodiment of the present invention; for conveniences, an optical device array comprising three columns (with reference to the vertical insulation layer) is illustrated. FIG. 5 is a partial exploded perspective view of the optical device array substrate in FIG. 4 showing the outline of the bottom side thereof. As shown in FIGS. 4 and 5, according to the optical device array substrate 100 having a built-in heat dissipating structure of the present invention, in the substrate 100, for example, aluminum or aluminum alloy substrate or copper or copper alloy substrate 110, more than two insulation layers (hereinafter referred to as ‘vertical insulation layer’) 112 penetrating substrate from up to bottom thereof are formed (see FIG. 1); thus, both segments of the substrate 110 located at each side of the vertical insulation layer 112 are electrically insulated from each other.

In such configuration, while a terminal, for example, an anode terminal at the one end of an optical device 120 disposed in any one column (referenced to a vertical insulation layer 112) is electrically connected to the substrate of the corresponding column via wire 122 and the like; a terminal, for example, a cathode terminal at the other end of said optical device is also electrically connected to another substrate of an adjacent column located at the other side of said vertical insulation layer 112 via wire 122 and the like. Therefore a segment of the substrate which is arranged at the end of the left side or at the end of the right side of the substrate could function as an anode and a cathode respectively. Reference number 116 in FIG. 4 represents a cavity comprising a concave pit hole having a downwardly narrowing taper formed across the two columns adjacent to the vertical insulation layer 112 for enhancing the efficiency of the reflected light from the optical device 120, and the optical device 120 and a wire 122 connected thereto are all accommodated inside of the cavity 116. Reference number 130 represents an encapsulant, wherein fluorescent materials and the like may be contained.

According to an exemplary embodiment of the present invention, under the substrate 110, multiple, preferably one in each row with respect to the optical device, and one in each column with respect to vertical insulation layer 112, coupling holes, for example, threaded coupling holes 114, for heat dissipating rods are formed. Thus it is preferred that the thickness of the substrate should be more than 5 mm to 20 mm.

Next, the heat dissipating rods 200 and 210 can be made of metal having excellent heat dissipation characteristics such as aluminum based material or aluminum alloy and the like, and the threaded tips 202 and 210 for screw-coupling to the coupling holes 114 are formed at the end of the rods. The diameters of such threaded tips 202 and 210 may be formed to have diameters less than that of the heat dissipating rods 200 and 210, or same diameters as that of the heat dissipating rods 200 and 210 instead.

Furthermore, to maintain heat dissipation characteristics and insulation function as well, remaining area of the heat dissipating rods 200 and 210 excluding the threaded tips 202 and 212 may be coated with insulation coating layers 204 and 214, and such insulation coating layers 204 and 214 may be implemented, for example, by anodizing or accomplished by direct deposition of insulation paint.

The shape of the cross-sections of the heat dissipating rods 200 and 210 are preferred to be a circular form but are not limited thereto, and it may be any shape, and for some instances, it may be hollow tube shape.

Meanwhile, the heat dissipating rods 200 and 210 may be functioned as electrodes; in this case, the exposed parts 206 that are formed after removing some portion of the insulation coating of the heat dissipating rods, for example, a heat dissipating rod 200 located at the left end, and any heat dissipating rod 200 located at the right end may be used as electrodes.

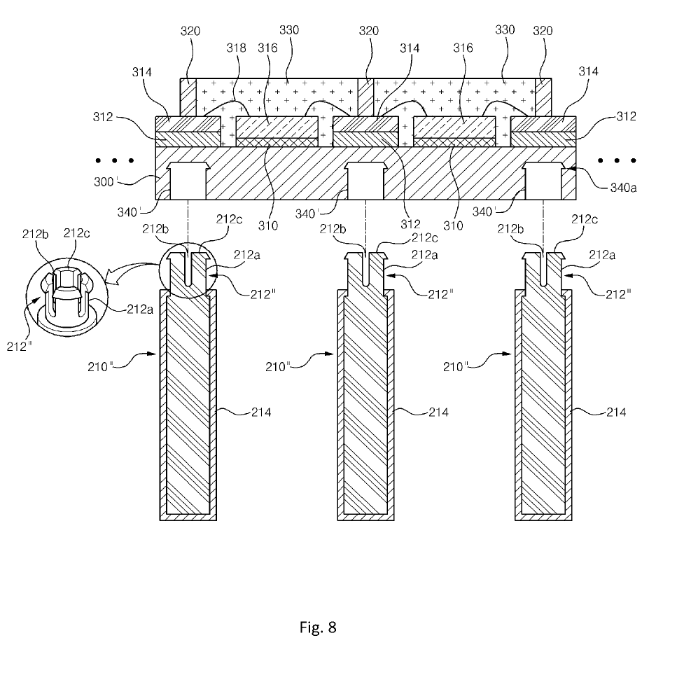

FIG. 6 is a cross-sectional view of an optical device array substrate having a vertical insulation coating layer among the optical device array substrate having a built-in heat dissipating structure according to an exemplary embodiment of the present invention; for conveniences, same reference numbers are assigned for the corresponding elements in FIG. 4, and their detailed descriptions are omitted. In the exemplary embodiment of FIG. 6, a coupling structure for coupling between the coupling hole 114′ and the coupling projection 202′ both having no threads is implemented; instead of screw-coupling the optical device array substrate 110′ and the heat dissipating rods 200′ and 210′, the diameters of the coupling projections 202′ and 212′ are maintained to be less than the diameters of the coupling holes 114′ prior to coupling by contracting the heat dissipating rods 200′ and 210′ under a sufficiently low sub-freezing temperature; at this point, the coupling projections 202′ and 212′ are coupled to the coupling holes 114′, and then the heat dissipating rods 200′ and 210′ are subjected to room temperature so as to expand the coupling projections 202′ and 212′ to their original state thereby accomplishing the coupling. In this case the diameters of the coupling projections 202′ and 212′ and the coupling holes 114′ may be maintained approximately equal to each other, or as circumstances require, as illustrated in the drawings, a tapered structure may be adopted wherein the diameters of the upper ends of the coupling holes 114′ and the coupling projections 202′ and 212′ are slightly larger than that of the bottom ends, thereby making separation difficult once they are coupled.

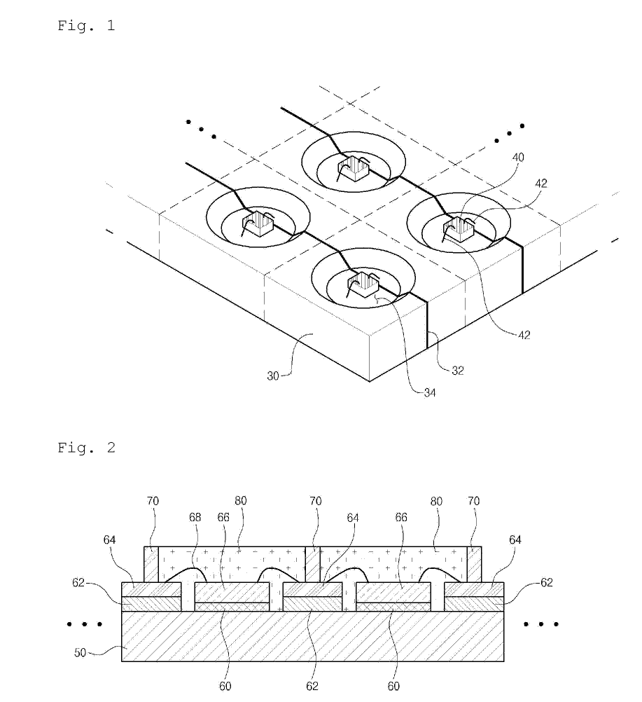

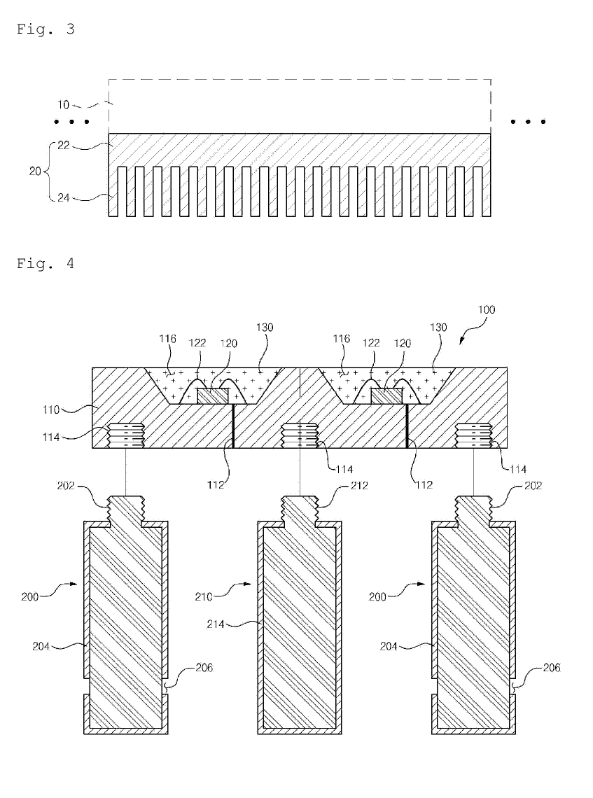

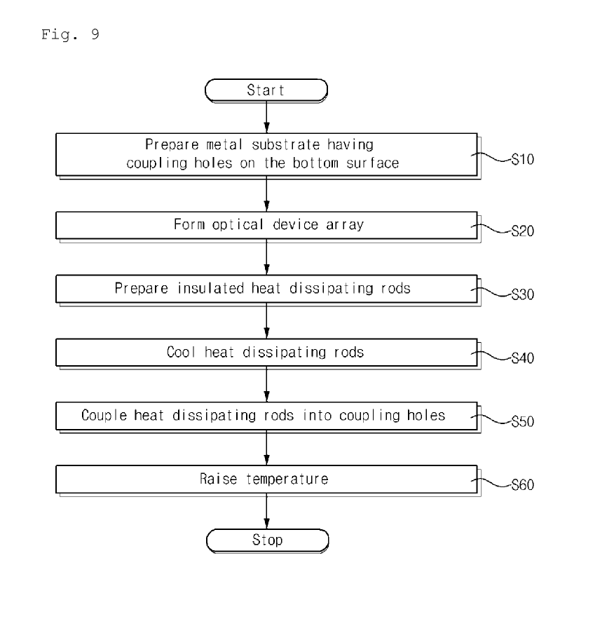

FIG. 7 is a cross-sectional view of an optical device array substrate having a horizontal insulation coating layer among the optical device array substrate having a built-in heat dissipating structure according to an exemplary embodiment of the present invention; same reference numbers are assigned for the corresponding elements in FIG. 4, and their detailed descriptions are omitted. In FIG. 7, reference number 300 represents a substrate, 310 represents an adhesive, 312 represents an insulation layer, 316 represents an optical device, 318 represents a wire, 320 represents a dam, and 330 represents an encapsulant respectively (see FIG. 2).

As reference number 340 represents a threaded coupling hole, 210 represents a coupling rod, 212 represents a threaded tip, and 214 represents a insulation coating layer respectively, this kind of structure may correspond to the optical device array substrate having a vertical insulation coating layer in FIG. 4. Similarly, the optical device array substrate as it is in FIG. 7 may be modified to a structure having coupling holes and coupling projections as shown in FIG. 6.

FIG. 8 is a cross-sectional view of an optical device array substrate having a horizontal insulation coating layer among the optical device array substrate having a built-in heat dissipating structure according to another exemplary embodiment of the present invention; same reference numbers are assigned for the corresponding elements in FIG. 7, and their detailed descriptions are omitted. In the exemplary embodiment of FIG. 8, the coupling projections 212″ of the heat dissipating rods 210″ are implemented as a hollow cylinder shape, and more than one (4 in this exemplary embodiment) lengthwise (along the axes) slots 212b are formed therein such that flexibility is allowed during coupling and the original form is recovered after coupling. In this case, at the end part of the coupling projection 212″ a latch structure is formed having a downwardly widening taper which means that the diameter of the upper end is equal or less than that of the body, such that it could be inserted by sliding into the coupling hole 340′ formed at the bottom of the optical device array substrate 300′; while the diameter of the bottom end of the latch structure is preferred to be larger than that of the coupling projection 212″, thereby making separation from the coupling hole 340′ difficult once they are coupled. It is also preferred that a latching groove 340a is formed at the upper end of the coupling hole 340′.

The coupling structure of the exemplary embodiment as it is in FIG. 8 may also be applied to the optical device array substrate having a vertical insulation coating layer in FIG. 4 through modification.

FIG. 9 is a flow diagram to describe manufacturing method of an optical device array substrate having a built-in heat dissipating structure according to an exemplary embodiment of the present invention, and it is a process flow chart for manufacturing of the optical device array substrate shown in FIG. 6. As illustrated in FIG. 9, at first, in step S10, a metal substrate having coupling holes formed on the bottom surface thereof is prepared; in step 20, optical devices are formed on the other surface of said substrate. Next, in steps S30 and S40, insulated heat dissipating rods are prepared and, said heat dissipating rods are contracted by cooling under freezing temperature. Next, in steps S50 and S60, the temperature of the coupling projections of the heat dissipating rods are elevated to room temperature while they are coupled to the coupling holes, thereby ending the process.

An optical device array substrate having a built-in heat dissipating structure, and method for manufacturing same of the present invention is not limited to the foregoing exemplary embodiments and various modifications can be made thereto without departing from the scope and spirit of the present invention. For example, unlike those foregoing exemplary embodiments, it may be applied to variously modified optical device array substrates including a structure where the optical device array substrate are comprised of a circular plate and a multiple optical devices are arranged in a radial pattern forming concentric circles and the like.

### DESCRIPTION OF SYMBOLS

| 110, 110′, 300, 300′: optical device array substrate, | |
|---|---|
| 112: vertical insulation layer, | 114: spiral coupling |

hole,

| | |
|---|---|
| 114′: coupling hole, | 116: cavity, |
| 120: optical device, | 122: wire, |

| 130: encapsulant, | |
|---|---|
| 200, 200′, 210, 210′: coupling rod, | |
| 202, 212: threaded tip, | 202′, 212′, 212″: coupling |

projection,

| | |
|---|---|
| 204, 214: insulation coating layer, | 206: exposed |

part,

| | |
|---|---|
| 310: adhesive, | 312: insulation layer, |
| 314: conduction layer, | 316: optical device, |
| 318: wire, | 320: dam, |
| 330: encapsulant, | 340: threaded coupling |

hole,

340′: coupling hole

What is claimed is:

1. An optical device array substrate having a built-in heat dissipating structure comprising:
an optical device array substrate having multiple optical devices disposed on its upper surface and multiple coupling holes formed on its bottom surface; and
a heat dissipating rod having a coupling projection formed on top thereof and being coupled into each of respective said coupling holes.

2. An optical device array substrate having a built-in heat dissipating structure according to claim 1, wherein:
said coupling holes are threaded and
said coupling projections are threaded and are screw-coupled to said coupling holes.

3. An optical device array substrate having a built-in heat dissipating structure according to claim 1, wherein:
each of said coupling holes has a downwardly narrowing taper, and
each of said coupling projections has a downwardly narrowing taper so as to be perfectly coupled into one of said coupling holes
and couple to said coupling holes even when shrunk under sub-freezing temperatures.

4. An optical device array substrate having a built-in heat dissipating structure according to claim 1, wherein:
said coupling projections are formed like a hollow cylinder shape having more than one lengthwise slot, and at the end part of each of said coupling projections a latch structure having a downwardly widening taper whose top end has a diameter equal or less than that of the body of the coupling projection while bottom end has a diameter greater than that of the body of the coupling projection is formed, and
said coupling holes a latching groove are formed therein for matching with the said latch structure.

5. An optical device array substrate having a built-in heat dissipating structure according to any one of claim 1, wherein:
insulation coating layers are formed on top surfaces of said heat dissipating rod except said coupling projections.

6. An optical device array substrate having a built-in heat dissipating structure according to claim 5, wherein:
a portion of said insulation coating layers in some of said heat dissipating rods are removed.

7. A manufacturing method of an optical device array substrate having a built-in heat dissipating structure comprising the steps of:
a) preparing a metal substrate formed with multiple coupling holes on the bottom surface thereof;
b) forming multiple optical devices on the top of said metal substrate;
c) preparing a heat dissipating rod formed with a coupling projection at the end part thereof for coupling with said coupling hole; and
d) coupling said coupling projection to said coupling hole after shrinking said heat dissipating rod under sub-freezing temperatures and raising to room temperature.

8. An optical device array substrate having a built-in heat dissipating structure according to claim 2, wherein:
insulation coating layers are formed on top surfaces of said heat dissipating g rod except said coupling projections.

9. An optical device array substrate having a built-in heat dissipating structure according to claim 3, wherein:
insulation coating layers are formed on top surfaces of said heat dissipating g rod except said coupling projections.

10. An optical device array substrate having a built-in heat dissipating structure according to claim 4, wherein:
insulation coating layers are formed on top surfaces of said heat dissipating g rod except said coupling projections.
